(19) United States
(12) Patent Application Publication
(10) Pub. No.: US 2016/0126337 A1
(43) Pub. Date: May 5, 2016

(54) SUBSTRATE PROCESSING APPARATUS, SEMICONDUCTOR DEVICE MANUFACTURING METHOD, AND SUBSTRATE PROCESSING METHOD

(71) Applicant: HITACHI KOKUSAI ELECTRIC INC., Tokyo (JP)

(72) Inventors: Tatsuya TOMINARI, Toyama-shi (JP); Atsushi MORIYA, Toyama-shi (JP); Kiyohisa ISHIBASHI, Toyama-shi (JP)

(73) Assignee: HITACHI KOKUSAI ELECTRIC INC., Tokyo (JP)

(21) Appl. No.: 14/894,620

(22) PCT Filed: May 29, 2014
(86) PCT No.: PCT/JP2014/064262

§ 371 Date: Nov. 30, 2015

(30) Foreign Application Priority Data
May 31, 2013 (JP) 2013-116232

(51) Int. Cl. H01L 29/66; C23C 16/24; H01L 21/02; C23C 16/44; C23C 16/52; H01L 21/3065; C23C 16/46; C23C 16/02

(52) U.S. Cl. CPC H01L 29/66636; C23C 16/46; C23C 16/24; C23C 16/0236; C23C 16/4412; C23C 16/52; H01L 21/3065; H01L 21/02532; H01L 21/02381

(57) ABSTRACT

A substrate processing apparatus includes a substrate having an SiGe film or Ge film exposed on at least a portion of a surface thereof, a process chamber configured to process the substrate, an etching gas supply part configured to supply an etching gas into the process chamber, a deposition gas supply part configured to supply gas containing at least an Si-containing gas as a deposition gas into the process chamber, and a control part configured to control the deposition gas supply part and the etching gas supply part so as to remove a Ge oxide film formed on a surface of the SiGe film or the Ge film by supplying the etching gas and to epitaxially grow an Si-containing film on at least the SiGe film or the Ge film by supplying the Si-containing gas after removing the Ge oxide film by the supply of the etching gas.

### TECHNICAL FIELD

The present invention relates to a substrate processing apparatus, a semiconductor device manufacturing method and a substrate processing method and, more particularly, to a process technique which forms a semiconductor film such as a silicon film or the like on a substrate such as a silicon wafer or the like by selective growth.

### BACKGROUND

In recent years, a demand has existed for a high drive speed and reduced power consumption in addition to miniaturization of semiconductor devices. However, due to the miniaturization of semiconductor devices, the length of a gate of a transistor element becomes short. This poses a new problem in that a leak current increases and it becomes more difficult to reduce power consumption. Conversely, if one tries to reduce a leak current, a new problem is posed in that the current drive speed of a transistor is reduced.

As one approach to this problem, a strained silicon (Si) technique draws attention. In this technique, a compressive stress or a tensile stress is applied to a channel region of a MOSFET (Metal Oxide Semiconductor Field Effect Transistor), thereby distorting a crystal lattice of Si and changing an energy band structure. Thus, the mobility of electrons and positive holes (holes) is improved by the reduction of carrier scattering attributable to lattice vibration or by the reduction of an effective mass.

In order to apply a compressive stress or a tensile stress to a channel region of a MOSFET, there has been proposed a transistor having a so-called embedded structure in which Si is epitaxially grown in a source/drain region. As an apparatus for realizing this epitaxial growth, there is available a substrate processing apparatus disclosed in, e.g., Patent document 1.

### PRIOR ART DOCUMENTS

### Patent Documents

Patent Document 1: Japanese laid-open publication No. 2011-216909

As a means for improving the performance of a semiconductor device other than the miniaturization thereof, the conversion from a planar two-dimensional structure to a fin-type three-dimensional structure or the use in a channel portion of a material such as silicon germanium (SiGe) or germanium (Ge) superior in the mobility of electrons and holes (positive holes) than Si have been studied.

The present disclosure provides a semiconductor device manufacturing method in which an SiGe film or a Ge film containing Ge atoms at a high concentration is used as a channel portion, a substrate processing method and a substrate processing apparatus under the consideration of the aforementioned problems.

### SUMMARY

According to one aspect of the present disclosure, there is provided a substrate processing apparatus, including: a process chamber configured to process a substrate having an impurity-containing SiGe film or an impurity-containing Ge film exposed on a portion of a surface of the substrate; an etching gas supply part configured to supply an etching gas into the process chamber; a deposition gas supply part configured to supply a deposition gas containing at least Si-atoms into the process chamber; and a control part configured to control the deposition gas supply part and the etching gas supply part so as to remove an impurity from a surface of the SiGe film or the Ge film by supplying the etching gas from the etching gas supply part into the process chamber and epitaxially grow an Si-containing film on the SiGe film or the Ge film by supplying the deposition gas containing Si atoms from the deposition gas supply part after removing the impurity by the supply of the etching gas.

According to another aspect of the present disclosure, there is provided a semiconductor device manufacturing method, including: transferring a substrate having an impurity-containing SiGe film or an impurity-containing Ge film exposed on a portion of a surface of the substrate to a process chamber; supplying an etching gas into the process chamber and removing an impurity from a surface of the SiGe film or the Ge film; and after removing the impurity, epitaxially growing an Si-containing film on the impurity-removed SiGe film or the impurity-removed Ge film by supplying a deposition gas containing at least Si atoms into the process chamber.

According to a further aspect of the present disclosure, there is provided a substrate processing method, including: transferring a substrate having an impurity-containing SiGe film or an impurity-containing Ge film exposed on a portion of a surface of the substrate to a process chamber; supplying an etching gas into the process chamber and removing an impurity from a surface of the SiGe film or the Ge film; and after removing the impurity, epitaxially growing an Si-containing film on the impurity-removed SiGe film or the impurity-removed Ge film by supplying a deposition gas containing at least Si atoms into the process chamber.

According to the present disclosure, it is possible to provide a substrate processing method, a semiconductor device manufacturing method and a substrate processing apparatus which are capable of improving the performance of a semiconductor device.

### BRIEF DESCRIPTION OF THE DRAWINGS

FIG. 1 is a schematic view illustrating the configuration of a substrate processing apparatus according to one embodiment of the present disclosure.

FIG. 2 is a vertical sectional view of a processing furnace of the substrate processing apparatus according to one embodiment of the present disclosure.

FIG. 3 is a flowchart illustrating the substrate processing process according to one embodiment of the present disclosure.

FIG. 4 is a graph showing etching rates in the case where substrate cleaning is performed using an HCl gas and a Cl₂ gas as an etching gas.

FIG. 5 is a flowchart illustrating a substrate cleaning process performed by H₂ annealing.

FIG. 6 is a graph obtained by analyzing an oxygen concentration and a carbon concentration in the respective interfaces of a Si substrate, an SiGe film and an Epi-Si (or Epi-SiGe) film serving as a cap layer in the case where substrate cleaning is performed by H₂ annealing.

FIG. 7 is a flowchart illustrating a substrate cleaning process performed by a pre-etching process using a Cl₂ gas.

FIG. 8 is a graph illustrating etching rates on a wafer when pre-etching is performed using a Cl₂ gas.

FIG. 9A is a graph showing a deposition time and a Si film thickness at the substrate center and the substrate edge in the case where a pre-etching process is not performed. FIG. 9B is a graph showing a deposition time and a Si film thickness at the substrate center and the substrate edge in the case where a pre-etching process is performed.

FIG. 10A is a view illustrating a state in which an STI portion and a channel portion having a fin-type structure are formed on a Si substrate. FIG. 10B is a view illustrating a state in which the channel portion is partially exposed by etching the STI portion. FIG. 10C is a view illustrating a state in which a cap layer is formed in the exposed channel portion. FIG. 10D is a view illustrating a state in which a gate insulation film and a gate film are formed on the cap layer.

FIG. 11A is a view illustrating a state in which an STI portion and a channel portion are formed on a Si substrate. FIG. 11B is a view illustrating a state in which a cap layer is formed on the channel portion. FIG. 11C is a schematic view of a semiconductor device in which a source portion, a drain portion and a gate portion are formed.

### DETAILED DESCRIPTION

### (Knowledge Obtained by the Inventors)

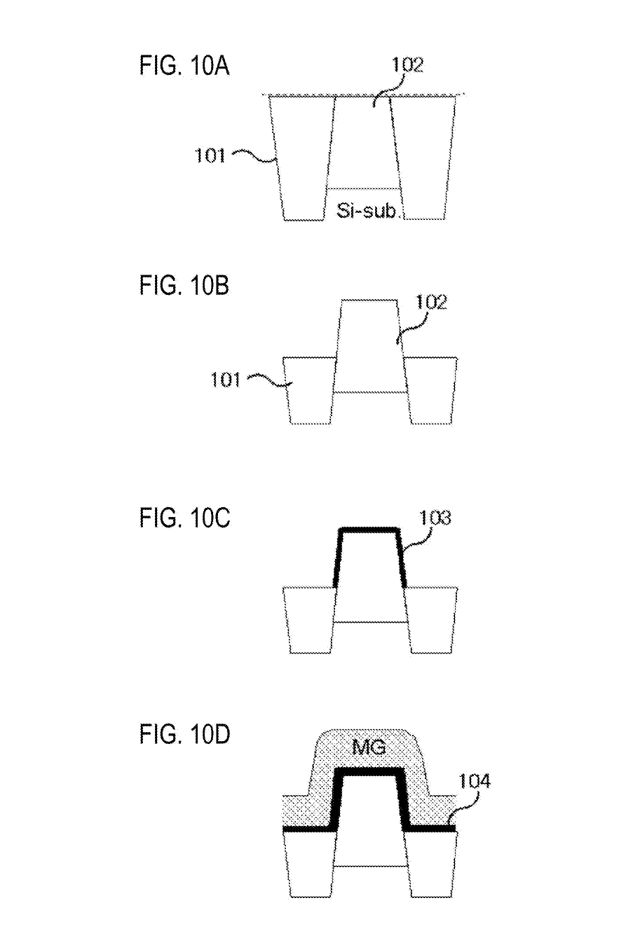

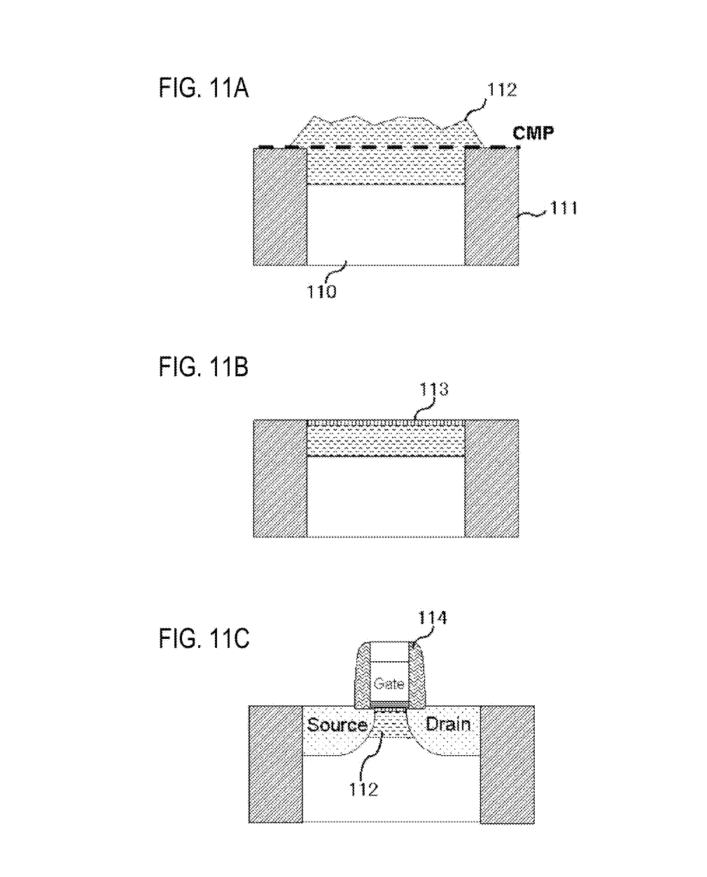

First, a manufacturing process of typical three-dimensional and planar semiconductor devices will be briefly described with reference to FIGS. 10A to 10D and 11A to 11C.

FIGS. 10A to 10D are views illustrating a deposition process of a fin-type semiconductor device using an SiGe film or a Ge film which contains Ge atoms at a high concentration. FIG. 10A is a view illustrating a state in which an STI (Shallow Trench Isolation) portion 101 and a channel portion 102 are formed on a Si substrate. After forming an STI portion 101 on a Si substrate, a channel region is recessed and epitaxial growth is performed in the recessed channel region. In the case where SiGe or Ge having a high concentration of Ge atoms is epitaxially grown as a channel, the growth becomes three-dimensional growth (Stranski-Krastanov (SK) mode growth) due to the strain caused by the difference in lattice constant between Si of the substrate and SiGe or Ge. Thus, there may be a case where the surface becomes rough. The surface is made planar by a CMP (Chemical Mechanical Polishing) process, an etching-back process or the like.

Thereafter, as illustrated in FIG. 10B, the STI portion 101 is etched in such a form as to partially expose the channel portion 102. If the channel portion 102 is exposed, as illustrated in FIG. 10C, an epitaxial film 103 of Si or SiGe serving as a cap layer (Hereinafter, epitaxial Si and epitaxial SiGe will be referred to as an Epi-Si and Epi-SiGe) is formed on the exposed channel portion.

If an Epi-Si or Epi-SiGe film 103 serving as a cap layer is formed, a high-K film used as a gate insulation film 104 is formed on the Epi-Si or Epi-SiGe film 103. A gate film such as a metal gate film (MG film) or the like is formed on the gate insulation film 104 as illustrated in FIG. 10D.

FIGS. 11A to 11C schematically illustrate a deposition process of a planar semiconductor device. Similar to FIG. 10A, FIG. 11A is a view illustrating a state in which an STI portion 111 and a channel portion 112 are formed on a Si substrate 110. Even in the planar type, similar to the three-dimensional type, if SiGe or Ge containing a high concentration of Ge atoms is epitaxially grown, there may be a case where SiGe or Ge is three-dimensionally grown and the surface of the substrate becomes rough. Thus, in order to make the channel portion 112 planar, the channel portion 112 is planarized by a CMP process or an etching-back process.

An Epi-Si or Epi-SiGe film serving as a cap layer is formed on the planarized channel portion 112 as illustrated in FIG. 11B. Finally, a source/drain portion and a gate portion 114 are formed to manufacture a semiconductor device illustrated in FIG. 11C.

In this regard, if SiGe or Ge containing Ge atoms at a high concentration is used as the channel portion of the semiconductor device, an interface state is generated in an interface between the SiGe or Ge film of the channel portion and the gate insulation film such as the high-K film or the like provided on the channel portion, by a Ge oxide film generated on the surface of the SiGe or Ge film. In order to suppress the generation of the interface state, it is necessary to form a cap layer such as an Si thin film or the like on the surface of the SiGe or Ge film of the channel portion.

However, even in a three-dimensional structure such as the fin type or the like or even in the case of a planar type, if SiGe or Ge containing Ge atoms at a high concentration is used, the surface becomes rough due to the large difference in lattice constant between SiGe or Ge and Si. It is therefore necessary to perform a planarizing process or the like by other devices such as a device for a CMP process or the like. For that reason, it is not possible to continuously perform Si deposition after SiGe deposition. There is a need to perform epitaxial growth of Si again on the SiGe or Ge growth surface. The substrate is exposed to the atmosphere when transferring the substrate to other devices for a CMP process or the like. Thus, a natural oxide film is formed on the substrate surface. Consequently, the interface between the epitaxial film of Si or SiGe (hereinafter referred to as an Epi-Si film or an Epi-SiGe film) serving as a cap layer and the channel portion does not become a clean interface. It is therefore impossible to obtain desired electrical properties. Herein, the SiGe containing Ge atoms at a high concentration refers to SiGe containing at least 50% or more of Ge atoms.

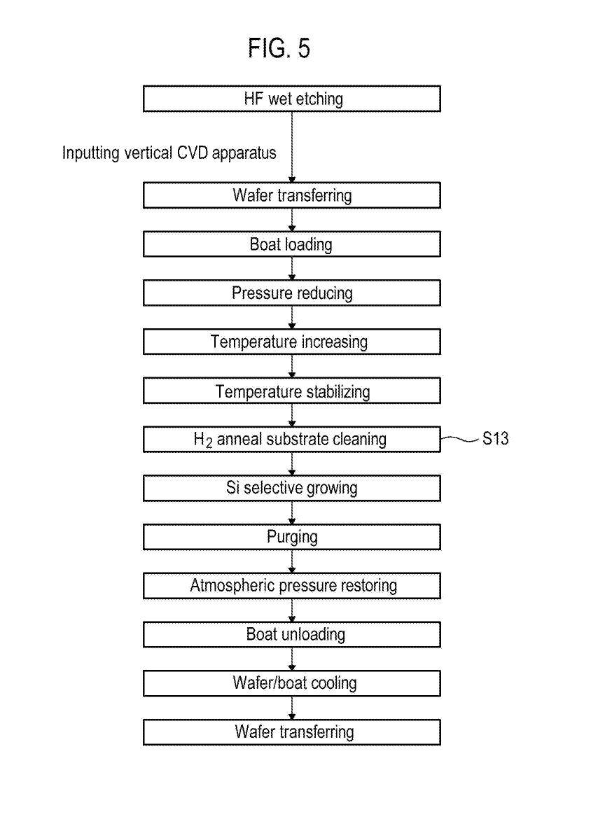

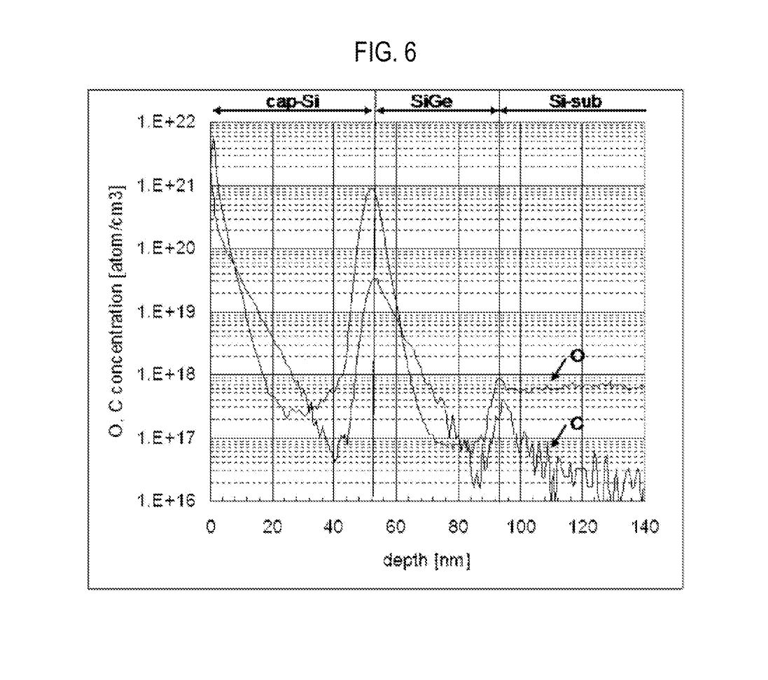

In general, hydrogen (H₂) annealing is performed to remove impurities existing on the film surface. As a technique of removing impurities, the use of substrate cleaning performed by H₂ annealing at a low temperature will now be described with reference to FIGS. 5 and 6. FIG. 5 is a flowchart illustrating a substrate surface cleaning process performed by H₂ annealing.

The H₂ annealing step S13 is a technique of removing impurities using a reducing action of hydrogen by performing a heat treatment under a hydrogen atmosphere. FIG. 6 is a graph obtained by analyzing an oxygen concentration and a carbon concentration in the respective interfaces of a Si substrate, an SiGe film and an Epi-Si (or Epi-SiGe) film serving as a cap layer in the case where substrate cleaning is performed by H₂ annealing for 30 minutes by setting the internal temperature of a process chamber at 550° C. in a temperature zone where the relaxation of an SiGe film as a channel portion does not occur and where the fin shape is not collapsed. The vertical axis in FIG. 6 indicates an oxygen concentration and a carbon concentration. The horizontal axis indicates the depth (nm) extending from the surface of an Epi-Si (or Epi-SiGe) film serving as a cap layer to the lower surface of a substrate.

As illustrated in FIG. 6, the processing was performed at a low temperature of 550° C. Therefore, the reducing effect of hydrogen was insufficient. The carbon concentration and the oxygen concentration in the interface between the SiGe film as a channel portion and the Epi-Si (or Epi-SiGe) film serving as a cap layer were very high. Thus, it can be confirmed that it is impossible to obtain a clean interface.

In the case where the interface between the channel portion and the cap layer is not clean as described above, the cap layer formed on the channel portion cannot have desired electrical properties. If the H₂ annealing is performed at a temperature at which impurities are sufficiently removed, a defect of strain relaxation or a shape collapse attributable to heat is generated in the channel portion.

The inventors have found that this phenomenon is a unique problem generated when an SiGe film or a Ge film containing Ge atoms at a high concentration is used as a channel portion.

The present disclosure is based on the aforementioned knowledge found by the inventors.

### First Embodiment

Next, one embodiment of the present disclosure will be described with reference to the drawings.

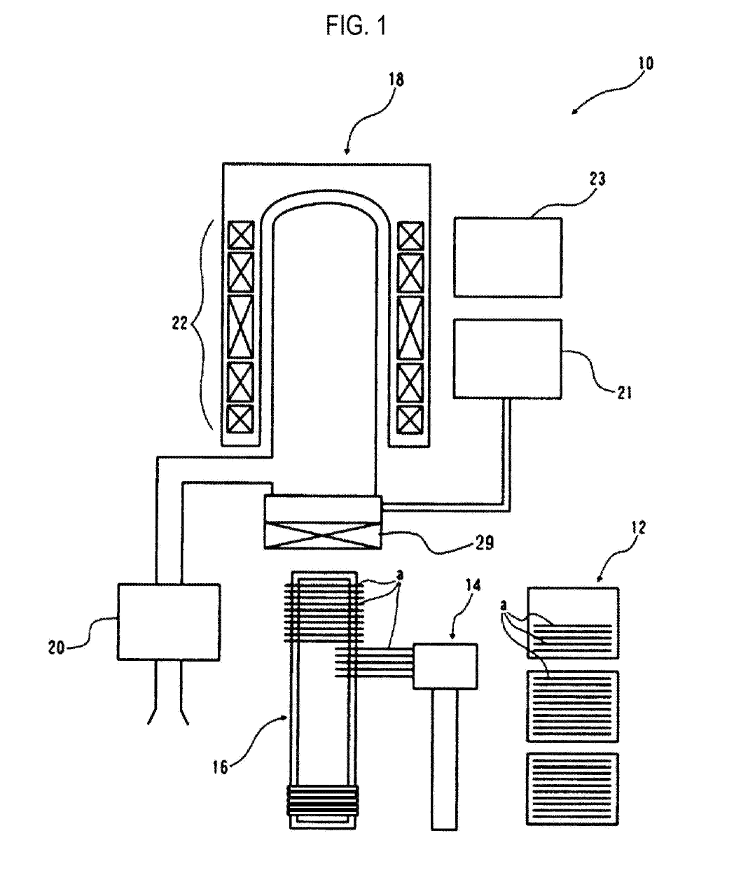

In FIG. 1, there is illustrated the outline of a substrate processing apparatus 10 according to one embodiment of the present disclosure. The substrate processing apparatus 10 is a so-called hot-wall-type vertical pressure-reducing CVD apparatus. As illustrated in FIG. 1, a wafer (Si substrate) loaded by a wafer cassette (also referred to as a FOUP or a pod) 12 is transferred from the wafer cassette 12 to a boat 16 as a substrate holding mechanism by a transfer machine 14. The transfer of the wafer a to the boat 16 is performed in a standby room. When the boat 16 exists in the standby room, the process chamber is kept air-tight by a furnace opening gate valve 29. If the transfer of all the wafers a to the boat 16 is completed, a furnace opening portion is opened by moving the furnace opening gate valve 29. The boat 16 is brought into a processing furnace 18. The interior of the processing furnace 18 is depressurized by a vacuum exhaust system 20. Then, the interior of the processing furnace 18 is heated to a desired temperature by a heater 22. After the temperature is stabilized, a source gas and an etching gas are alternately supplied from a gas supply part 21. Si or SiGe is selectively epitaxially grown on the wafer a. Reference numeral 23 designates a control system that controls the insertion of the boat 16 into the processing furnace 18, the rotation of the boat 16, the discharge of the boat 16 from the processing furnace 18, the exhaust in the vacuum exhaust system 20, the supply of the gases from the gas supply part 21, the heating performed by the heater 22, and so forth.

A Si-containing gas such as SiH₄, Si₂H₆, SiH₂Cl₂ or the like is used as a source gas for the selective epitaxial growth of Si or SiGe. In the case of SiGe, a Ge-containing gas such as GeH₄, GeCl₄ or the like is further used. If the source gas is introduced for a CVD reaction, growth is immediately started on Si. In contrast, a growth delay called a latency period (incubation time) occurs on an insulation film of SiO₂ or SiN. The growth of Si or SiGe only on Si during the latency period is referred to as selective growth. During the selective growth, the formation of an Si nucleus (the formation of a discontinuous Si film) occurs on the insulation film of SiO₂ or SiN, thereby impairing the selectivity. Thus, after supplying the source gas, the etching gas is supplied to perform the removal of the Si nucleus (Si film) formed on the insulation film of SiO₂ or SiN. Selective epitaxial growth is performed by repeating the above procedure.

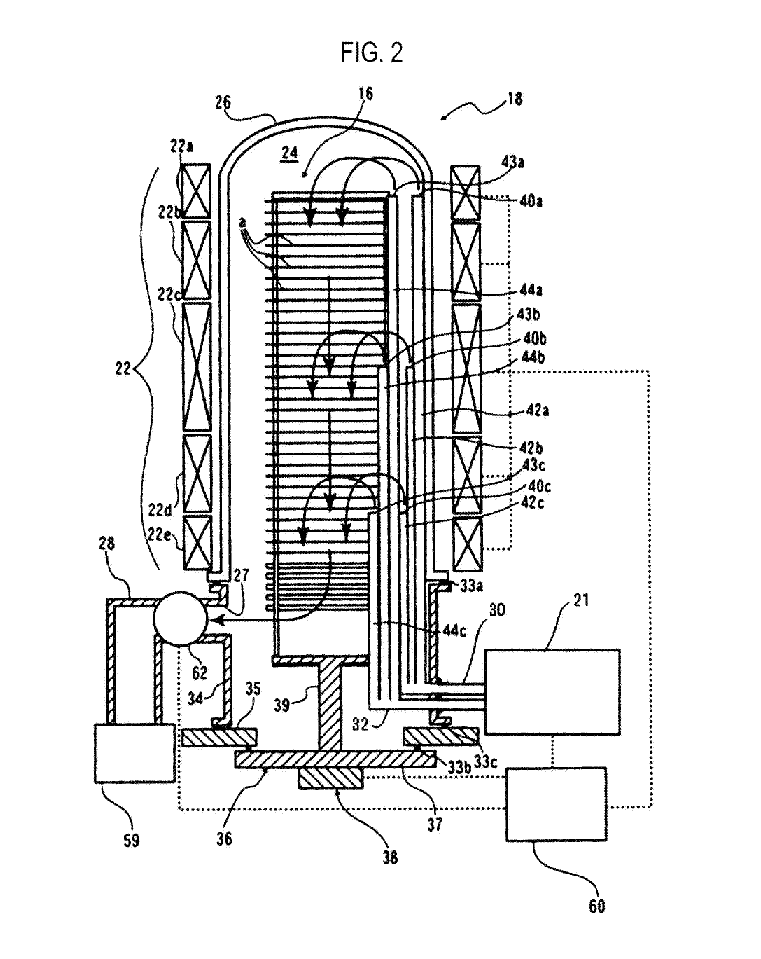

Next, the details of the configuration of the processing furnace 18 used in the substrate processing apparatus 10 according to one embodiment of the present disclosure, which is available after the insertion of the boat 16, will be described with reference to the drawings. FIG. 2 is a schematic configuration diagram or a vertical sectional view of the processing furnace 18 according to one embodiment of the present disclosure, which is available after the insertion of the boat 16. As illustrated in FIG. 2, a reaction tube 26 configured to form a process chamber 24 and formed of, e.g., an outer tube, a gas exhaust pipe 28 disposed under the reaction tube 26 and configured to exhaust gases from an exhaust port 27, a first gas supply system 30 configured to supply a source gas or the like into the process chamber 24 and a second gas supply system 32 configured to supply an etching gas or the like, are installed in the processing furnace 18. The processing furnace 18 includes a manifold 34 connected to the reaction tube 26 through an O-ring 33a, a seal cap 36 configured to close the lower end portion of the manifold 34 and to seal the process chamber 24 through O-rings 33b and 33c, a boat 16 as a wafer holder (substrate support member) configured to hold (support) wafers (Si substrates) a at multiple stages, a rotary mechanism 38 configured to rotate the boat 16 at a predetermined revolution number, and a heater (heating member) 22 disposed outside the reaction tube 26 and configured to heat the wafers a, the heater 22 including heater wires and insulation members not illustrated.

The reaction tube 26 is made of a heat-resistant material, e.g., quartz (SiO₂) or silicon carbide (SiC). The reaction tube 26 is formed in a cylindrical shape with the upper end portion thereof closed and the lower end portion thereof opened. The manifold 34 is made of, e.g., stainless steel. The manifold 34 is formed in a cylindrical shape with the upper end portion and the lower end portion thereof opened. The upper end portion of the manifold 34 engages with the reaction tube 26 through the O-ring 33a. The seal cap 36 is made of, e.g., stainless steel. The seal cap 36 includes a ring-shaped portion 35 and a disc-shaped portion 37. The seal cap 36 closes the lower end portion of the manifold 34 through O-rings 33b and 33c. Furthermore, the boat 16 is made of a heat-resistant material, e.g., quartz or silicon carbide. The boat 16 is configured to keep (hold and support) a plurality of wafers a in a horizontal posture and at multiple stages with the centers of the wafers a aligned with one another. The rotary mechanism 38 of the boat 16 includes a rotary shaft 39 extending through the seal cap 36 and connected to the boat 16. The rotary mechanism 38 is configured to rotate the boat 16, thereby rotating the wafers a.

Furthermore, the heater 22 is divided into five regions, namely an upper heater 22A, a central upper heater 22B, a central heater 22C, a central lower heater 22D and a lower heater 22E, each of which has a cylindrical shape.

Three first gas supply nozzles 42a, 42b and 42c having first gas supply holes 40a, 40b and 40c differing in heights from one another are disposed within the processing furnace 18. The first gas supply nozzles 42a, 42b and 42c constitute the first gas supply system 30. In addition to the first gas supply nozzles 42a, 42b and 42c, three second gas supply nozzles 44a, 44b and 44c having second gas supply holes 43a, 43b and 43c differing in height from one another are disposed within the processing furnace 18. The second gas supply nozzles 44a, 44b and 44c constitute the second gas supply system 32. The first gas supply system and the second gas supply system are connected to the gas supply part 21.

In this configuration of the processing furnace 18, a source gas (e.g., SiH₄ gas) is supplied from the first gas supply nozzles 42a, 42b and 42c of the first gas supply system 30 to three points, namely an upper portion, a central portion and a lower portion, of the boat 16. An etching gas (e.g., a Cl₂ gas or an HCl gas) is supplied from the second gas supply nozzles 44a, 44b and 44c of the second gas supply system 32 to three points, namely an upper portion, a central portion and a lower portion, of the boat 16. While the source gas is supplied from the first gas supply system 30, a purge gas (e.g., an H₂ gas) is supplied from the second gas supply system 32. While the etching gas is supplied from the second gas supply system 32, a purge gas is supplied from the first gas supply system 30. This prevents the other gas from flowing back into the nozzles. The internal atmosphere of the process chamber 24 is exhausted from the gas exhaust pipe 28 as an exhaust system. An exhaust means (e.g., a vacuum pump 59) is connected to the gas exhaust pipe 28. The gas exhaust pipe 28 is installed at the lower portion of the process chamber 24. As illustrated in FIG. 2, the gas injected from the gas supply nozzles 42 and 44 flows from the upper portion toward the lower portion. By allowing the gas to flow from the upper portion toward the lower portion in this way, it is possible to provide a configuration in which the gas passed through the lower portion of the process chamber 24, which has a low temperature and to which a byproduct adheres with ease, does not make contact with the substrates a. It is also possible to expect the improvement of a film quality.

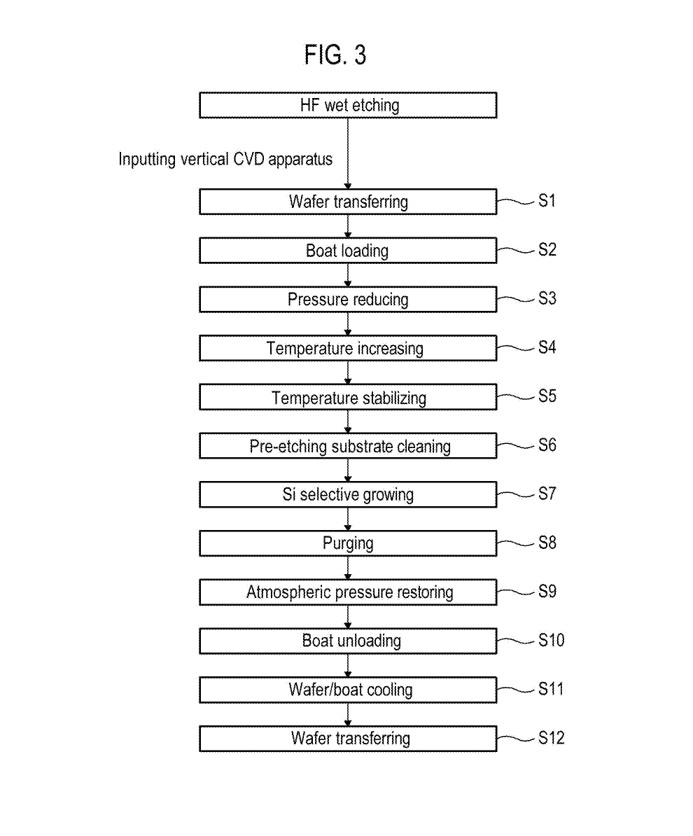

Next, descriptions will be made on a substrate processing process, which is one process of a semiconductor device manufacturing method performed by the substrate processing apparatus of the present embodiment. FIG. 3 is a flowchart of the substrate processing process according to one embodiment of the present disclosure. The substrate processing process of the present embodiment includes a wafer carry-in step S1, a boat loading (boat carry-in) step S2, a pressure reducing step S3, a temperature increasing step S4, a temperature stabilizing step S5, a pre-etching substrate cleaning step S6, an Si selective growth step S7, a purge step S8, an atmospheric pressure restoring step S9, a boat unloading (boat carry-out) step S10, a wafer/boat cooling step S11 and a wafer transfer step S12. The substrate processing process according to the present embodiment will now be described in detail.

### (Wafer Carry-In Step S1)

The cassette 12 holding the wafers a processed by other apparatuses (for example, subjected to HF wet etching) is carried into the substrate processing apparatus 10 by an in-factory transfer device (not illustrated) such as an OHT or the like. If the cassette 12 is conveyed to the substrate processing apparatus 10, the transfer machine 14 charges the wafer a from the cassette 12 to the boat 16 (wafer carry-in step S1). The transfer machine 14 which has delivered the wafer a to the boat 16 returns to the cassette 12 and charges the next wafer a to the boat 16. The wafers a charged into the boat 16 are supported in a horizontal posture and at multiple stages with the centers thereof aligned with one another. In the present embodiment, the wafers a are formed of monocrystalline silicon. Insulation films such as silicon oxide films or silicon nitride films, which serve as insulator surfaces, are partially formed on the surfaces of the wafers a. The surfaces of the wafers a are partially exposed between the insulation films. The exposed portions are monocrystalline silicon portions which serve as semiconductor surfaces. SiGe or Ge epitaxial layers containing Ge atoms at a high concentration are formed on the monocrystalline silicon portions. SiGe or Ge is exposed on the surface.

### (Boat Loading Step S2)

If a predetermined number of wafers a are charged to the boat 16 (wafer charging), the boat 16 is moved up by a boat elevator not illustrated (boat loading step S2). Then, the boat 16 holding a group of the wafers a is carried into the processing furnace 18 by the upward movement of the boat elevator (boat loading). The opening of the lower end portion of the manifold 34 is closed by the seal cap 36. The boat elevator is stopped. When the boat 16 is accommodated within the process chamber 24, the internal temperature of the process chamber 24 is set at 400° C. or less.

### (Pressure Reducing Step S3)

Subsequently, the interior of the process chamber 24 is evacuated by the vacuum exhaust system 20 so that the internal pressure of the process chamber 24 becomes a desired pressure (vacuum degree) (pressure reducing step S3). At this time, the internal pressure of the process chamber 24 is measured by a pressure sensor not illustrated. Based on the pressure thus measured, an exhaust valve (e.g., an APC valve) 62 is feed-back controlled by a control device 60.

### (Temperature Increasing Step S4 and Temperature Stabilizing Step S5)

Furthermore, the interior of the process chamber 24 is heated by the heater 22 so that the internal temperature of the process chamber 24 becomes a desired temperature (temperature increasing step S4). At this time, the amount of an electric current supplied to the heater 22 is feed-back controlled by the control device 60 based on the temperature information detected by a temperature sensor not illustrated, so that the internal temperature of the process chamber 24 becomes 500° C. or more and less than 600° C. After the pressure reducing step S3 and before the temperature increasing step S4, the rotary mechanism 38 is rotated. The wafers a are rotated as the boat 16 is rotated by the rotary mechanism 38. The substrate processing apparatus 10 waits until the internal temperature of the process chamber 24 is stabilized, for example, until the internal temperature of the process chamber 24 becomes, e.g., 550° C. (temperature stabilizing step S5).

### (Pre-Etching Substrate Cleaning Step S6)

Next, pre-etching is performed on the wafers a using a pre-etching gas. In the present embodiment, a hydrogen chloride (HCl) gas is used as the pre-etching gas. At the pre-etching substrate cleaning step S6, the HCl gas is supplied from the gas supply part 21 into the reaction tube via the second gas supply system 32. The flow rate of the HCl gas is adjusted by a gas flow rate adjusting means such as an MFC or a flow rate control valve. The flow-rate-adjusted HCl gas is supplied from the second gas supply holes 43a, 43b and 43c of the second gas supply nozzles 44a, 44b and 44c of the second gas supply system 32 to the upper portion, the central portion and the lower portion of the boat 16. Then, the HCl gas is moved down within the process chamber 24 and is exhausted from the gas exhaust pipe 28.

During this pre-etching substrate cleaning step, the heater 22 is controlled to adjust the internal temperature of the process chamber 24 so as to fall within a temperature range of 500° C. or more and less than 600° C. in which the HCl gas is activated and in which strain is not generated in the SiGe or Ge film as a base film. The HCl gas has a small reaction force and is not activated at a temperature of less than 500° C. Furthermore, at a temperature of 600° C. or more, strain is generated in the SiGe or Ge film as a base film containing Ge atoms at a high concentration. Thus, it is impossible to obtain desired electrical properties. Furthermore, the processing temperature range at this step is from 550° C. or more to less than 600° C. in some embodiments. By processing the wafer in a temperature zone of from 550° C. or more to less than 600° C. in this way, it is possible to restrain halogen atoms, which become a growth inhibition factor of an Si or SiGe epitaxial film, from remaining on the wafer surface in the case where, instead of merely performing etching, it is necessary to have an Si or SiGe film epitaxially grown on the wafer surface available after etching. This makes it possible to form a good Si or SiGe epitaxial film.

Furthermore, the internal pressure of the process chamber 24 is set to fall within, e.g., a range of 100 to 600 Pa, by adjusting the exhaust valve 62. The reason for this is as follows. The HCl gas has a small reaction force. Therefore, if the internal pressure of the process chamber 24 is lower than 100 Pa, it is impossible to obtain a desired etching rate and it is difficult to etch an object. If the internal pressure of the processing furnace is higher than 600 Pa, it is difficult to obtain a uniform etching rate.

In this regard, it is preferred that the SiGe film or the Ge film containing Ge atoms at a high concentration, which is the channel portion to be cleaned at the pre-etching substrate cleaning step S6, is processed so that the surface roughness thereof becomes 1 nm or less (0.3 nm or less in the case of RMS notation). By processing the SiGe film or the Ge film at this surface roughness, it becomes possible to form a uniform cap layer on the channel portion.

### (Si Selective Growth Step S7)

At the Si selective growth step S7, deposition, namely epitaxial selective growth of Si using an SiGe or Ge film as a base, is performed on the wafer a. As one example, a specific example of epitaxial selective growth of Si will be described below.

(1) First, the source gas is supplied from the gas supply part 21 to the first gas supply system 30, whereby the source gas is supplied from the first gas supply holes 40a, 40b and 40c of the first gas supply nozzles 42a, 42b and 42c into the process chamber 24. The source gas is, e.g., an SiH₄ gas. The flow rate of the source gas is adjusted by an MFC or a flow rate adjusting valve connected to the gas supply part 21 controlled by the control device 60. The flow-rate-adjusted source gas is moved into the first gas supply nozzles 42a, 42b and 42c and is supplied from the first gas supply holes 40a, 40b and 40c into the process chamber 24 while being heated by the heater 22 (deposition step).

In this case, a hydrogen (H₂) gas as a carrier gas may be supplied at the same time. The flow rate of the H₂ gas as a carrier gas supplied into the process chamber 24 is adjusted by an WC or a flow rate adjusting valve connected to the gas supply part 21 controlled by the control device 60. The flow-rate-adjusted source gas is introduced into the first gas supply nozzles 42a, 42b and 42c and is supplied from the first gas supply holes 40a, 40b and 40c into the process chamber 24 while being heated by the heater 22.

(2) Subsequently, the supply of the source gas and the H₂ gas is stopped and the evacuation of the interior of the process chamber 24 is performed. After the evacuation of the interior of the process chamber 24 has been completed, an inert gas such as a nitrogen (N₂) gas or a H₂ gas, which serves as a purge gas, is supplied to the first gas supply nozzles 42a, 42b and 42c or the second gas supply nozzles 44a, 44b and 44c or both, thereby purging the internal atmosphere of the process chamber 24 (purge step in the selective growth step).

(3) Thereafter, the etching gas is supplied to the second gas supply system 32. The etching gas is, e.g., a chlorine (Cl₂) gas, and is supplied from the second gas supply holes 43a, 43b and 43c into the process chamber 24 via the second gas supply nozzles 44a, 44b and 44c (etching step).

(4) Thereafter, the supply of the etching gas is stopped and the evacuation of the interior of the process chamber 24 is performed. After the evacuation of the interior of the process chamber 24 has been completed, an inert gas such as a nitrogen (N₂) gas or a H₂ gas, which serves as a purge gas, is supplied from the first gas supply system 30 or the second gas supply system 32 or both, thereby purging the internal atmosphere of the process chamber 24 (purge step in the selective growth step).

The selective epitaxial growth step (Si selective growth step S7) is performed by repeating one cycle including the aforementioned steps (1) to (4) until the Si epitaxial film has a desired thickness.

At this time, the exhaust valve 62 is appropriately adjusted and the internal pressure of the process chamber 24 is set to become, e.g., less than 100 Pa. The flow rate of the source gas, e.g., the SiH₄ gas, is set to fall within, e.g., a range of 0 to 1,000 sccm. The flow rate of the H₂ gas is set to fall within, e.g., a range of 0 to 20,000 sccm. Depending on the process, the flow rate of the Cl₂ gas as the etching gas is set to fall within a range of 0 to 100 sccm.

### (Purge Step S8 and Atmospheric Pressure Restoring Step S9)

Next, the supply of the gases to the first gas supply system 30 and the second gas supply system 32 is stopped, thereby stopping the supply of the source gas, the H₂ gas and the etching gas into the process chamber. Then, the inert gas such as a nitrogen gas or the like is supplied from the gas supply part 21 into the process chamber 24 via the first gas supply system 30 or the second gas supply system 32 or both. The purge step S8 is carried out at which the source gas, the etching gas and the reaction product remaining within the process chamber 24 after the completion of the Si selective growth step S7 are discharged from the gas exhaust pipe 28 together with the inert gas.

In this way, the interior of the process chamber 24 is purged and the internal atmosphere of the process chamber 24 is replaced by the inert gas (purge step S8). If the purge of the interior of the process chamber 24 is completed, the inert gas is supplied into the process chamber 24 while adjusting the opening degree of the exhaust valve 62 of the gas exhaust pipe 28, thereby restoring the internal pressure of the process chamber 24 to atmospheric pressure (atmospheric pressure restoring step S9).

### (Boat Unloading Step S10 to Wafer Transfer Step S12)

Thereafter, the rotary mechanism 38 is stopped to stop the rotation of the wafers a. The boat elevator is moved down to move the seal cap 36 downward, thereby opening the lower end portion of the manifold 34. The boat 16 is moved down and is unloaded from the process chamber 24 (boat unloading step S10). Subsequently, a period is set during which the boat 16 charged with the wafers a waits until the wafers a and the boat are cooled (wafer/boat cooling step S11). If the wafers a are cooled, the processed wafers a are taken out from the boat 16 by the wafer transfer machine and are transferred to the wafer cassette 12 (wafer carry-out step S12). The wafer cassette 12 holding the processed wafers a is removed from the substrate processing apparatus 10 by an in-factory transfer device not illustrated. The substrate processing process according to the present embodiment is performed by the steps S1 to S12 described above.

### (Comparison of the Substrate Cleaning Performed by Cl₂ Etching Process and the Substrate Cleaning Performed by HCl Etching Process)

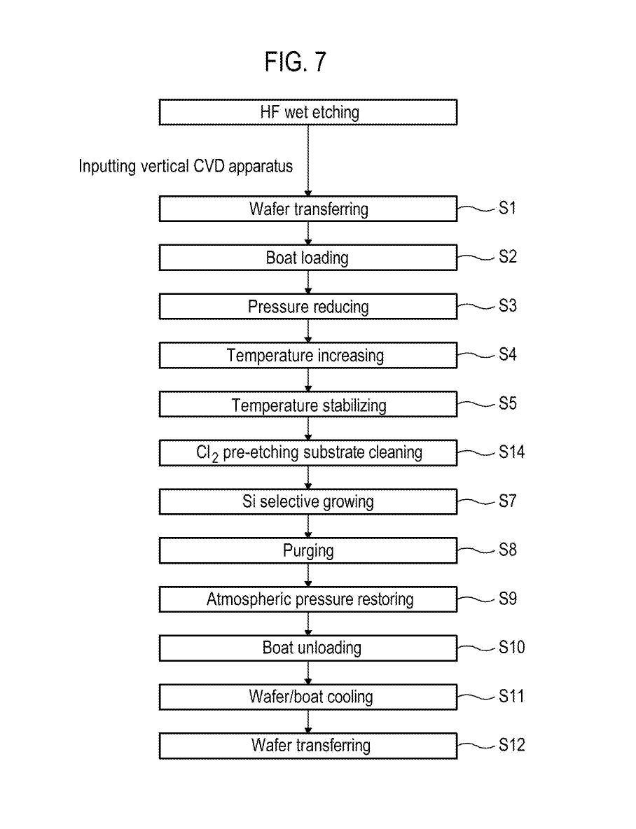

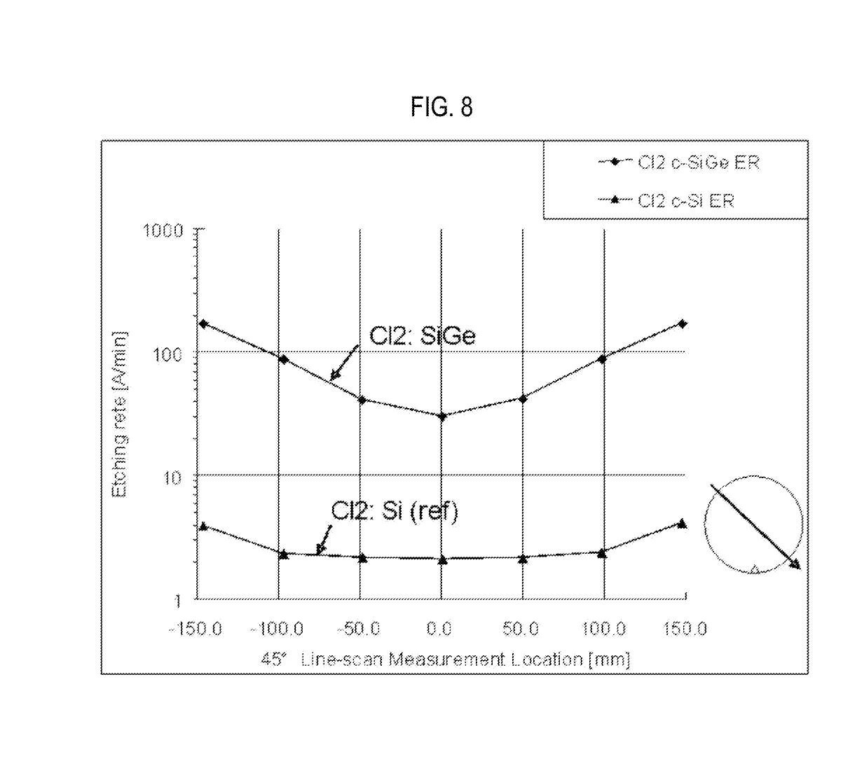

Next, the substrate cleaning performed using a Cl₂ gas as an etching gas will be described with reference to FIGS. 7 and 8. FIG. 7 is a flowchart of a process in which the substrate cleaning is performed by a pre-etching process using a Cl₂ gas. FIG. 7 differs in Cl₂ pre-etching step S14 from FIG. 3. Other steps are the same as those of FIG. 3.

In the case where the Cl₂ gas is used in the pre-etching process, the etching rate depends largely on the material which becomes a base. This is because Cl₂ is stronger in etching force than HCl.

FIG. 8 is a graph illustrating the etching rates on the wafer when the pre-etching is performed using a Cl₂ gas under the conditions where the types of the film to be etched are Si and SiGe and the internal temperature of the process chamber is set to be 550° C. in a temperature zone where the relaxation of an SiGe film does not occur and where the shape is not collapsed. The vertical axis in the graph illustrated in FIG. 8 indicates the etching rates (Å/min). The horizontal axis indicates the positions on the substrate surface. The value 0.0 described at the center of the horizontal axis indicates the position of the substrate center.

As illustrated in FIG. 8, it can be confirmed that, while the etching rate in the case of the etching target being Si is about 4 Å/min in the position of the substrate end portion (where the horizontal axis value is −150.0 or 150.0), the etching rate in the same position in the case of the etching target being SiGe is about 200 Å/min which is about 50 times as large as the etching rate of about 4 Å/min. Similarly, while the etching rate in the case of the etching target being Si is about 2 Å/min in the position of the substrate center (where the horizontal axis value is 0.0), the etching rate in the same position in the case of the etching target being SiGe is about 30 Å/min which is about 15 times as large as the etching rate of about 2 Å/min.

Accordingly, when the pre-etching is performed using a Cl₂ gas, the etching rate is very high in the case of SiGe. Therefore, complex and delicate control is needed in order to uniformly clean the SiGe or Ge film formed in the channel portion.

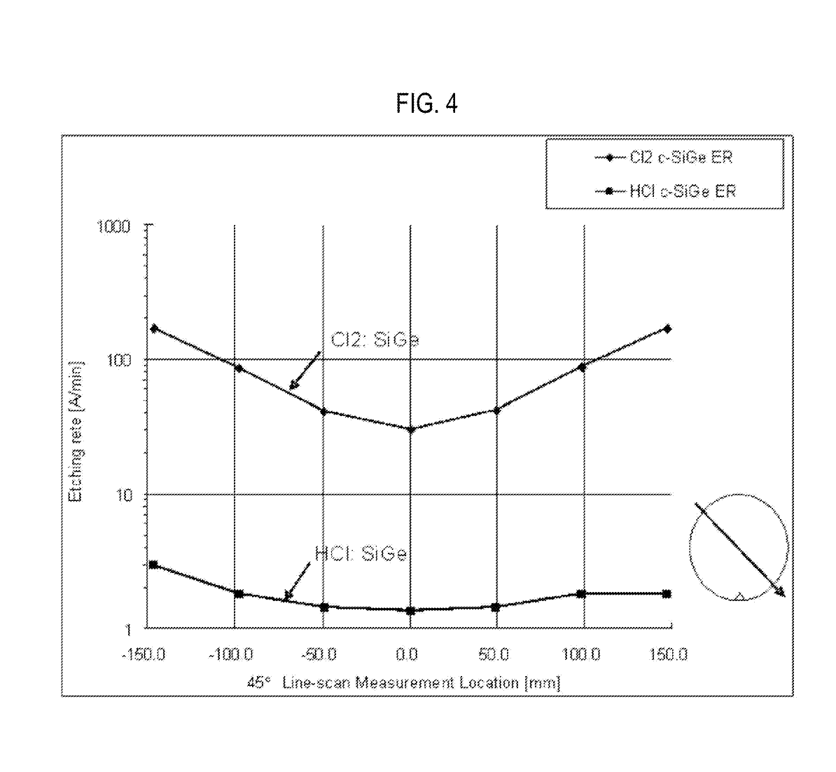

FIG. 4 illustrates the measurement result of etching rates in the case where substrate cleaning is performed using an HCl gas and a Cl₂ gas as an etching gas with the type of the film to be etched being SiGe. In FIG. 4, the parameters indicated by the vertical axis and the horizontal axis of the graph are the same as those of FIG. 8.

As illustrated in FIG. 4, when the substrate cleaning is performed using the HCl gas as the etching gas, the etching rate in the position of one substrate end portion (where the horizontal axis value is −150.0) is 3 Å/min which is slightly higher than the etching rate in the position of the other substrate end portion (where the horizontal axis value is 150.0). However, the etching rate in the region from the substrate center to the substrate end portions is 1 to 2 Å/min. It is therefore possible to obtain a substantially uniform etching rate.

(Comparison of Incubation Time of Si Film with and without Pre-Etching Process)

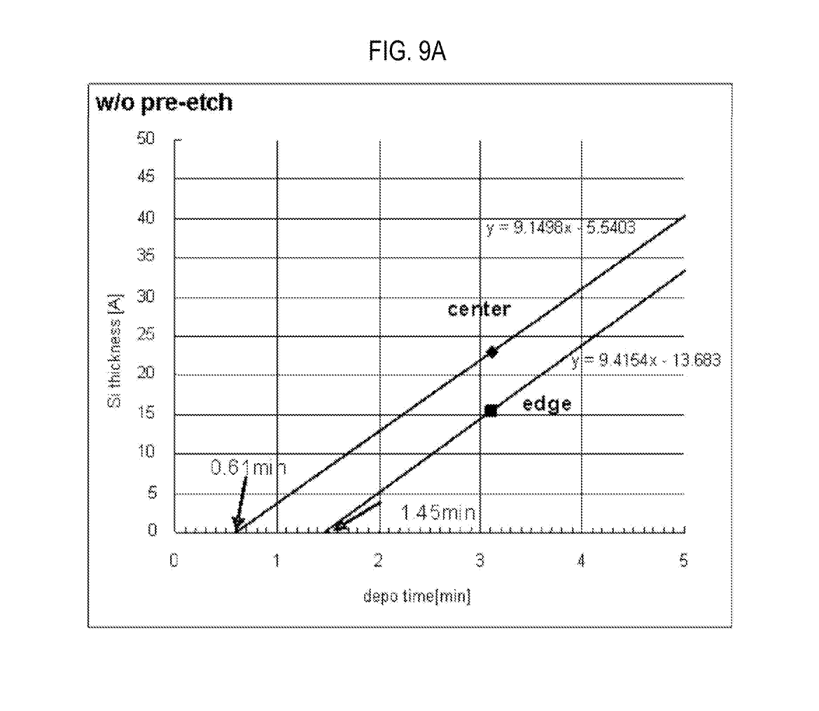

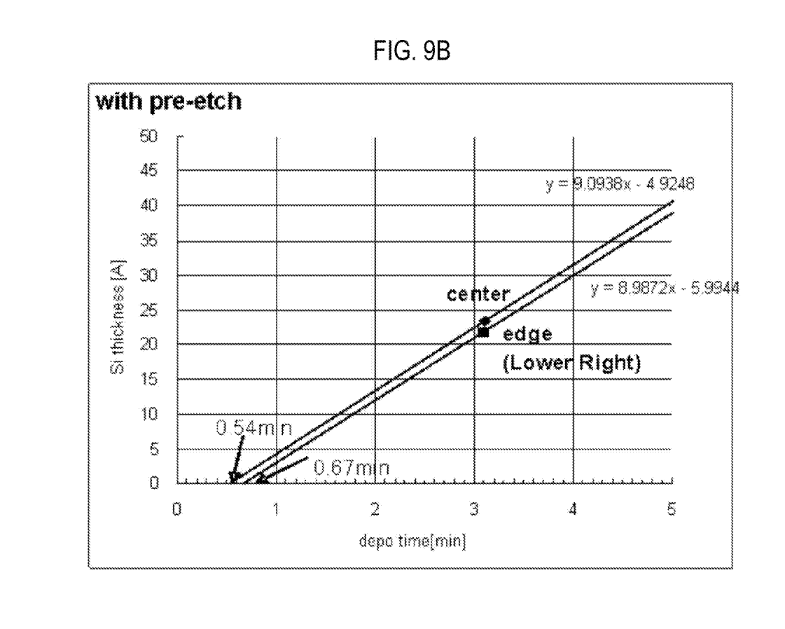

Next, a graph which compares the deposition times of a Si film as a cap layer with and without a pre-etching process is shown in FIGS. 9A and 9B. FIG. 9A is a graph showing a deposition time and a Si film thickness at the substrate center and the substrate edge when a pre-etching process is not performed. FIG. 9B is a graph showing a deposition time and a Si film thickness at the substrate center and the substrate edge when a pre-etching process is performed. The vertical axis of the graphs shown in FIGS. 9A and 9B indicates a Si film thickness. The horizontal axis indicates a deposition time.

When the pre-etching process is not performed, as shown in FIG. 9A, the incubation time for the formation of a Si film at the substrate center is 0.61 min but the incubation time at the substrate edge is 1.45 min. Thus, the incubation time varies greatly even on the same substrate surface.

In contrast, if the pre-etching process is performed, as shown in FIG. 9B, the incubation time for the formation of a Si film at the substrate center is 0.54 min and the incubation time for the formation of a Si film at the substrate edge is 0.67 min. Thus, no large difference in the incubation time occurs on the same substrate surface.

According to the present embodiment described above, it is possible to achieve one or more effects set forth below.

According to the present embodiment, in the substrate or the semiconductor device which includes an SiGe or Ge film containing Ge atoms at a high concentration, cleaning can be performed by etching the surface in-situ after depositing the SiGe or Ge film. Therefore, as compared with a case where the surface is etched ex-situ, it is possible to reduce a risk such as damage of the substrate or the semiconductor device or formation of a natural oxide film which may be generated when moving the substrate or the semiconductor device to other apparatuses. It is also possible to improve the processing throughput of the substrate or the semiconductor device.

Furthermore, according to the present embodiment, in the substrate or the semiconductor device which includes an SiGe or Ge film, cleaning can be performed by etching the surface at a low temperature. It is therefore possible to maintain a desired film quality without generating relaxation of strain, deformation, damage or the like in the SiGe or Ge film.

Moreover, according to the present embodiment, it is possible to perform control by which the SiGe or Ge film is uniformly etched at a desired amount. Therefore, it is possible to obtain a uniform surface roughness so that the surface roughness of the SiGe or Ge film containing Ge atoms at a high concentration becomes 1 nm or less (0.3 nm or less in the case of RMS notation). It is also possible to obtain a clean surface which becomes an interface with a cap film. It becomes possible to suppress variations in the incubation time of the Si or SiGe epitaxial film formed on the SiGe or Ge film. It becomes possible to deposit the Si or SiGe epitaxial film that exhibits good crystallinity.

While embodiments of the present disclosure have been described, the respective embodiments described above may be appropriately combined with one another. Even in this case, it is possible to obtain the aforementioned effects. The present disclosure is not limited to the embodiments described above but may be differently modified without departing from the spirit thereof.

For example, in the embodiments described above, descriptions have been made on the case where the SiGe or Ge film containing Ge atoms at a high concentration is formed in the channel portion. However, the formation region of the SiGe or Ge film is not limited to the channel portion but may be any region of a semiconductor device in which Epi-Si or Epi-SiGe is deposited on an SiGe or Ge film containing Ge atoms at a high concentration, which is formed on a Si substrate.

In the aforementioned embodiments, descriptions have been made on the vertical batch-type substrate processing apparatus which uses a boat as a substrate holder. However, the present disclosure is not limited thereto. The substrate processing apparatus may be a single-wafer-type substrate processing apparatus or a single-wafer-type and batch-type substrate processing apparatus.

Hereinafter, some preferred aspects of the present disclosure will be additionally described as supplementary notes.

### (Supplementary Note 1)

A substrate processing apparatus, including: a process chamber configured to process a substrate having an impurity-containing SiGe film or an impurity-containing Ge film exposed on a portion of a surface of the substrate; an etching gas supply part configured to supply an etching gas into the process chamber; a deposition gas supply part configured to supply a deposition gas containing at least Si atoms into the process chamber; and a control part configured to control the deposition gas supply part and the etching gas supply part so as to remove an impurity from a surface of the SiGe film or the Ge film by supplying the etching gas from the etching gas supply part into the process chamber and epitaxially grow an Si-containing film on the SiGe film or the Ge film by supplying the deposition gas containing Si atoms from the deposition gas supply part after removing the impurity by the supply of the etching gas.

### (Supplementary Note 2)

A semiconductor device manufacturing method, including: transferring a substrate having an impurity-containing SiGe film or an impurity-containing Ge film exposed on a portion of a surface of the substrate to a process chamber; supplying an etching gas into the process chamber and removing an impurity from a surface of the SiGe film or the Ge film; and after removing the impurity, epitaxially growing an Si-containing film on the impurity-removed SiGe film or the impurity-removed Ge film by supplying a deposition gas containing at least Si atoms into the process chamber.

### (Supplementary Note 3)

A substrate processing method, including: transferring a substrate having an impurity-containing SiGe film or an impurity-containing Ge film exposed on a portion of a surface of the substrate to a process chamber; supplying an etching gas into the process chamber and removing an impurity from a surface of the SiGe film or the Ge film; and after removing the impurity, epitaxially growing an Si-containing film on the impurity-removed SiGe film or the impurity-removed Ge film by supplying a deposition gas containing at least Si atoms into the process chamber.

### (Supplementary Note 4)

A substrate manufacturing method, including: transferring a substrate having an impurity-containing SiGe film or an impurity-containing Ge film exposed on a portion of a surface of the substrate to a process chamber; supplying an etching gas into the process chamber and removing an impurity from a surface of the SiGe film or the Ge film; and after removing the impurity, epitaxially growing an Si-containing film on the impurity-removed SiGe film or the impurity-removed Ge film by supplying a deposition gas containing at least Si atoms into the process chamber.

### (Supplementary Note 5)

The substrate processing apparatus, the semiconductor device manufacturing method, the substrate processing method and the substrate manufacturing method of Supplementary Notes 1 to 4, further including: a heating device configured to heat an interior of the process chamber, wherein the control part is configured to control the heating device so that an internal temperature of the process chamber becomes 500° C. or more and less than 600° C. before supplying the etching gas.

### (Supplementary Note 6)

The substrate processing apparatus, the semiconductor device manufacturing method, the substrate processing method and the substrate manufacturing method of Supplementary Notes 1 to 4, wherein the etching gas is a hydrogen chloride gas.

### (Supplementary Note 7)

The substrate processing apparatus, the semiconductor device manufacturing method, the substrate processing method and the substrate manufacturing method of Supplementary Notes 1 to 4, wherein the deposition gas is an SiH₄ gas, an H₂ gas or a Cl₂ gas.

### (Supplementary Note 8)

The substrate processing apparatus, the semiconductor device manufacturing method, the substrate processing method and the substrate manufacturing method of Supplementary Notes 1 to 4, wherein the Si-containing film serving as a cap is an Epi-Si film or an Epi-SiGe film.

### (Supplementary Note 9)

A substrate processing apparatus, including: a substrate having an SiGe film or a Ge film exposed on a portion of a surface of the substrate; a process chamber configured to process the substrate; a heating device configured to heat an interior of the process chamber to a predetermined temperature; a deposition gas supply part configured to supply a deposition gas containing at least Si atoms into the process chamber; an etching gas supply part configured to supply a hydrogen chloride gas as an etching gas into the process chamber; and a control part configured to control the heating device, the deposition gas supply part and the etching gas supply part so as to heat the interior of the process chamber to a temperature of 500° C. or more and less than 600° C., remove an impurity from a surface of the SiGe film or the Ge film by supplying the hydrogen chloride gas from the etching gas supply part after heating the interior of the process chamber, and form a film serving as a cap on the SiGe film or the Ge film by supplying the deposition gas containing Si atoms from the deposition gas supply part after removing the impurity by the supply of the hydrogen chloride gas.

### INDUSTRIAL USE OF THE PRESENT INVENTION

As described above, the present disclosure can be utilized in a semiconductor device manufacturing method, a substrate processing method and a substrate processing apparatus capable of improving the performance of a semiconductor device.

### EXPLANATION OF REFERENCE NUMERALS

a: wafer, 21: gas supply part, 22: heater, 24: process chamber, 27: exhaust port, 28: gas exhaust pipe, 60: control device (control part)

1. A substrate processing apparatus, comprising:
a process chamber configured to process a substrate having an SiGe film or a Ge film exposed on at least a portion of a surface of the substrate;
an etching gas supply part configured to supply an etching gas into the process chamber;
a deposition gas supply part configured to supply gas containing at least an Si-containing gas as a deposition gas into the process chamber; and
a control part configured to control the deposition gas supply part and the etching gas supply part so as to remove a Ge oxide film formed on a surface of the SiGe film or the Ge film by supplying the etching gas and to epitaxially grow an Si-containing film on at least the SiGe film or the Ge film by supplying the Si-containing gas after removing the Ge oxide film by the supply of the etching gas.

2. The apparatus of claim 1, wherein the etching gas is hydrogen chloride.

3. The apparatus of claim 2, further comprising:
a heating device configured to heat an interior of the process chamber,
wherein the control part is configured to control the heating device so that an internal temperature of the process chamber when supplying the etching gas becomes 500° C. or more and less than 600° C.

4. The apparatus of claim 2, further comprising:
an exhaust part configured to exhaust an internal atmosphere of the process chamber,
wherein the control part is configured to control the exhaust part so that an internal pressure of the process chamber when supplying the etching gas becomes 100 Pa or more and less than 600 Pa.

5. The apparatus of claim 1, wherein the SiGe film or the Ge film includes at least 50% or more of Ge atoms.

6. A semiconductor device manufacturing method, comprising:
transferring a substrate having an SiGe film or a Ge film exposed on at least a portion of a surface of the substrate to a process chamber;
after transferring the substrate, supplying an etching gas from an etching gas supply part into the process chamber and removing a Ge oxide film formed on a surface of the SiGe film or the Ge film; and
after removing the Ge oxide film, epitaxially growing an Si-containing film on at least the surface of the SiGe film or the Ge film by supplying at least an Si-containing gas as a deposition gas from a deposition gas supply part into the process chamber.

7. The method of claim 6, wherein the etching gas is hydrogen chloride.

8. The method of claim 7, wherein a heating device configured to heat an interior of the process chamber is controlled so that an internal temperature of the process chamber when removing the Ge oxide film becomes 500° C. or more and less than 600° C.

9. The method of claim 7, wherein an exhaust part configured to exhaust an internal atmosphere of the process chamber and the etching gas supply part are controlled so that an internal pressure of the process chamber when removing the Ge oxide film becomes 100 Pa or more and less than 600 Pa.

10. The method of claim 6, wherein the SiGe film or the Ge film includes at least 50% or more of Ge atoms.

11. A substrate processing method, comprising:
transferring a substrate having an SiGe film or a Ge film exposed on at least a portion of a surface of the substrate to a process chamber;
after transferring the substrate, supplying an etching gas from an etching gas supply part into the process chamber and removing a Ge oxide film formed on a surface of the SiGe film or the Ge film; and
after removing the Ge oxide film, epitaxially growing an Si-containing film on at least the surface of the SiGe film or the Ge film by supplying at least an Si-containing gas as a deposition gas from a deposition gas supply part into the process chamber.

12. The method of claim 11, wherein the etching gas is hydrogen chloride.

13. The method of claim 12, wherein a heating device configured to heat an interior of the process chamber is controlled so that an internal temperature of the process chamber when removing the Ge oxide film becomes 500° C. or more and less than 600° C.

14. The method of claim 12, wherein an exhaust part configured to exhaust an internal atmosphere of the process chamber and the etching gas supply part are controlled so that an internal pressure of the process chamber when removing the Ge oxide film becomes 100 Pa or more and less than 600 Pa.

15. The method of claim 11, wherein the SiGe film or the Ge film includes at least 50% or more of Ge atoms.
